(19) United States
(12) Patent Application Publication
(10) Pub. No.: US 2020/0266292 A1
(43) Pub. Date: Aug. 20, 2020

(54) COMPOSITE SUBSTRATES OF CONDUCTIVE AND INSULATING OR SEMI-INSULATING SILICON CARBIDE FOR GALLIUM NITRIDE DEVICES

(71) Applicants: RUIGANG LI, LOS ANGELES, CA (US); NA REN, LOS ANGELES, CA (US); ZHENG ZUO, LOS ANGELES, CA (US)

(72) Inventors: RUIGANG LI, LOS ANGELES, CA (US); NA REN, LOS ANGELES, CA (US); ZHENG ZUO, LOS ANGELES, CA (US)

(73) Assignee: AZ Power, Inc, CULVER CITY, CA (US)

(21) Appl. No.: 16/515,977

(22) Filed: Jul. 18, 2019

Related U.S. Application Data
(60) Provisional application No. 62/807,689, filed on Feb. 19, 2019.

(51) Int. Cl. H01L 29/778; H01L 29/20; H01L 21/02; H01L 29/66

(52) U.S. Cl. CPC H01L 29/7786; H01L 29/2003; H01L 21/02447; H01L 29/66462; H01L 21/0254; H01L 21/0262; H01L 21/02378

(57) ABSTRACT

In one aspect, a semiconductor device comprising an electronic conductive Silicon Carbide (SiC) substrate; a semi-insulating or insulating SiC epitaxial layer formed on the electronic conductive SiC substrate; and a Gallium Nitride (GaN) device formed on the semi-insulating or insulating SiC epitaxial layer. In one embodiment, the semi-insulating or insulating SiC epitaxial layer is grown directly on the SiC substrate through chemical vapor deposition (CVD). In another embodiment, the GaN device is a high electron mobility transistor (HEMT).

### CROSS-REFERENCE TO RELATED APPLICATIONS

This application claims priority under 35 U.S.C. § 119(e) to U.S. Provisional Patent Application Ser. No. 62/807,689, filed on Feb. 19, 2019, the entire contents of which are hereby incorporated by reference.

### FIELD OF THE INVENTION

The present invention relates to semiconductor devices and, more particularly, to Gallium Nitride (GaN) semiconductor devices on a composite substrate.

### BACKGROUND OF THE INVENTION

Nowadays, silicon power devices have reached the physical limit due to a small bandgap (1.12 eV) of silicon material. Wide bandgap materials, such as silicon carbide and gallium nitride, emerged in these decades and have attracted a lot of interests in high power, high temperature and/or high frequency application. Both of the two materials have advantages of wide band-gap and high breakdown electric field strength. Especially, GaN has better electron transport properties than silicon.

One successful GaN power device, which is attracting attention for high power and/or high frequency applications in recent years, is the High Electron Mobility Transistor (HEMT). In this device, a barrier layer made of AlGaN and a channel layer made of GaN are laminated, and cause a high concentration two-dimensional electron gas (2DEG) to occur in a lamination interface due to a large polarization effect. The two-dimensional electron gas is formed in an accumulation layer in the unintentionally doped semiconductor material. It can contain a very high sheet electron concentration and have much higher mobility due to a reduced ion impurity scattering effect.

GaN HEMTs have been offered commercially since 2006, and have found immediate use in various wireless infrastructure applications due to their high efficiency and high voltage operation. A second generation of devices with shorter gate lengths will address higher frequency telecom and aerospace applications.

Conventional GaN HEMTs have been fabricated on a single crystal semi-insulating base substrate having a composition different from GaN, such as silicon, sapphire and SiC. Usually, a buffer layer such as a strained-superlattice layer or a low-temperature growth buffer layer is formed as an initially-grown layer on the base substrate. Accordingly, a configuration in which a barrier layer, a channel layer, and a buffer layer are epitaxially formed on a base substrate is the most basic configuration of the HEMT device. Among silicon, sapphire and SiC materials, SiC is more attractive for the single crystal semi-insulating base substrate due to smaller mismatch coefficient and high thermal conductivity.

However, the cost of the SiC semi-insulating substrate can be high due to the difficulty of growing a single crystal semi-insulating SiC wafer. Therefore, there remains a need for a new and improved composite substrate to overcome the problems stated above.

### SUMMARY OF THE INVENTION

It is an object of the present invention to provide a GaN semiconductor device formed on a composite substrate including a conductive SiC substrate and an insulating/semi-insulating SiC epitaxial layer.

It is another object of the present invention to provide a cost-effective composite substrate including a conductive SiC substrate and an insulating/semi-insulating SiC epitaxial layer where a GaN semiconductor device can be formed.

It is a further object of the present invention to provide a composite substrate including a conductive SiC substrate and an insulating/semi-insulating SiC epitaxial layer that is easy to manufacture.

In one aspect, the present invention provides a SiC semi-insulating or insulating epitaxial layer on a conductive SiC substrate. A GaN-based device structure, such as a GaN based transistor structure is provided on a device substrate, which is formed by the composite substrate of SiC semi-insulating epitaxial layer and conductive SiC substrate.

In one embodiment, the conductive SiC substrate may be n-type doped with nitrogen or phosphorus. In another embodiment, the conductive SiC substrate may be p-type doped with aluminum or boron. It is noted that electrically conductive substrates may be easier and/or less expensive to produce in larger sizes and/or with higher structural quality than semi-insulating or insulating substrates.

In one embodiment, the semi-insulating or insulating epitaxial layer can be grown with chemical vapor deposition (CVD) method directly on the conductive SiC substrate. Because the semi-insulating or insulating epitaxial layer is formed by homo-epitaxial growth, it is much easier to be thickly grown comparing to conventional hetero-epitaxial films. Furthermore, the conductive SiC substrate is a higher quality substrate for the semi-insulating or insulating epitaxial layer comparing with conventional semi-insulating substrate. Additionally, the semi-insulating or insulating epitaxial layer grown on conductive SiC substrate is much easier and less expensive instead of growing on a single crystal semi-insulating SiC wafer.

In some embodiments of the present invention, the SiC epitaxial layer has a thickness of at least about 5 μm. In other embodiments, the SiC epitaxial layer has a thickness of at least about 10 μm.

In some embodiments of the present invention, the SiC epitaxial layer has a resistivity of at least 10⁵ Ωcm. The SiC epitaxial layer may have an isolation voltage of at least about 50V. In other embodiments, an isolation voltage of at least about 10V. In one embodiment, the conductive substrate has a resistivity of equal to or less than about 0.01 Ωcm at room temperature.

It is noted that the SiC epitaxial layer can be made from the Fermi level pinning effect by compensating shallow donor and acceptor levels from residual impurities with intrinsic deep level defects.

### BRIEF DESCRIPTION OF THE DRAWINGS

FIG. 1 is a schematic view of a GaN device on a composite substrate including a conductive SiC substrate and an insulating/semi-insulating SiC epitaxial layer in the present invention.

FIG. 2 is a flow diagram of a method for manufacturing a semiconductor device with the composite substrate in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Gallium Nitride (GaN) is a binary III/V direct bandgap semiconductor commonly used in light-emitting diodes since the 1990s. The compound is a very hard material that has a Wurtzite crystal structure. Its special properties of a wide band gap of 3.4 eV enables it for applications in optoelectronic, high-power and high-frequency devices. For example, GaN is the substrate which makes violet (405 nm) laser diodes possible, without use of nonlinear optical frequency-doubling.

As stated above, among silicon, sapphire and SiC materials, SiC is more attractive for the single crystal semi-insulating base substrate due to smaller mismatch coefficient and high thermal conductivity. However, the cost of the SiC semi-insulating substrate can be high due to the difficulty of growing a single crystal semi-insulating SiC wafer. The present invention is to provide a cost-effective composite substrate that includes a conductive SiC substrate and an insulating/semi-insulating SiC epitaxial layer. Also, the composite substrate in the present invention is easy to manufacture.

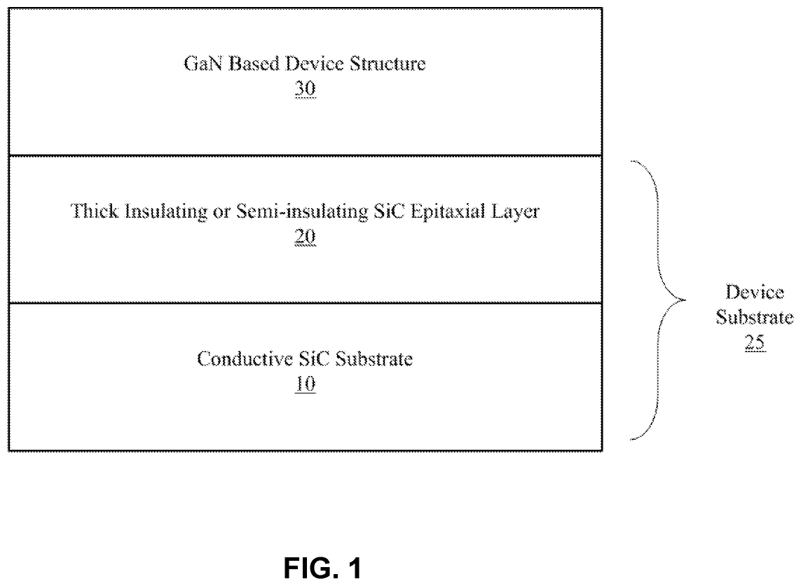

As shown in FIG. 1, in one aspect, the present invention provides a SiC semi-insulating or insulating epitaxial layer 20 on a conductive SiC substrate 10. A GaN-based device structure 30, such as a GaN based transistor structure is provided on a device substrate 25, which is formed by the composite substrate of SiC semi-insulating epitaxial layer 20 and conductive SiC substrate 10.

In one embodiment, the conductive SiC substrate 10 may be n-type doped with nitrogen or phosphorus. In another embodiment, the conductive SiC substrate 10 may be p-type doped with aluminum or boron. It is noted that electrically conductive substrates may be easier and/or less expensive to produce in larger sizes and/or with higher structural quality than semi-insulating or insulating substrates.

In one embodiment, the semi-insulating or insulating epitaxial layer 20 can be grown with chemical vapor deposition (CVD) method directly on the conductive SiC substrate 10. Because the semi-insulating or insulating epitaxial layer 20 is formed by homo-epitaxial growth, it is much easier to be thickly grown comparing to conventional hetero-epitaxial films. Furthermore, the conductive SiC substrate 10 is a higher quality substrate for the semi-insulating or insulating epitaxial layer 20 comparing with conventional semi-insulating substrate. Additionally, the semi-insulating or insulating epitaxial layer 20 grown on conductive SiC substrate 10 is much easier and less expensive instead of growing on a single crystal semi-insulating SiC wafer.

In some embodiments of the present invention, the SiC epitaxial layer 20 has a thickness of at least about 5 μm. In other embodiments, the SiC epitaxial layer 20 has a thickness of at least about 10 μm.

In some embodiments of the present invention, the SiC epitaxial layer 20 has a resistivity of at least 10⁵ Ωcm. The SiC epitaxial layer 20 may have an isolation voltage of at least about 50V and, in other embodiments, an isolation voltage of at least about 10V. In one embodiment, the conductive substrate 10 has a resistivity of equal to or less than about 0.010 cm at room temperature. It is noted that the SiC epitaxial layer can be made from the Fermi level pinning effect by compensating shallow donor and acceptor levels from residual impurities with intrinsic deep level defects.

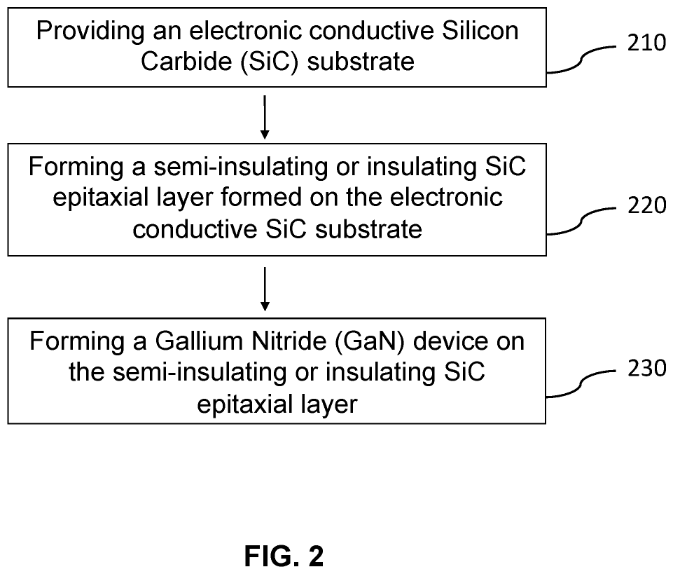

In another aspect, as shown in FIG. 2, a method for manufacturing a semiconductor device comprising steps of providing an electronic conductive Silicon Carbide (SiC) substrate 210; forming a semi-insulating or insulating SiC epitaxial layer formed on the electronic conductive SiC substrate 220; and forming a Gallium Nitride (GaN) device on the semi-insulating or insulating SiC epitaxial layer 230.

In one embodiment, in step 220, the semi-insulating or insulating epitaxial layer can be grown with chemical vapor deposition (CVD) method directly on the conductive SiC substrate. In some embodiments, the SiC epitaxial layer has a thickness of at least about 5 μm. In other embodiments, the SiC epitaxial layer has a thickness of at least about 10 μm.

In some embodiments of the present invention, the SiC epitaxial layer has a resistivity of at least 10⁵ Ωcm. The SiC epitaxial layer may have an isolation voltage of at least about 50V and, in other embodiments, an isolation voltage of at least about 10V.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A semiconductor device comprising:
an electronic conductive Silicon Carbide (SiC) substrate;
a semi-insulating or insulating SiC epitaxial layer formed on the electronic conductive SiC substrate; and
a Gallium Nitride (GaN) device formed on the semi-insulating or insulating SiC epitaxial layer.

2. The semiconductor device of claim 1, wherein a thickness of the semi-insulating or insulating SiC epitaxial layer is at least 5 μm.

3. The semiconductor device of claim 1, wherein a thickness of the semi-insulating or insulating SiC epitaxial layer is at least 10 μm.

4. The semiconductor device of claim 1, wherein the semi-insulating or insulating SiC epitaxial layer is grown directly on the conductive SiC substrate through chemical vapor deposition (CVD).

5. The semiconductor device of claim 1, wherein a resistivity of the semi-insulating or insulating SiC epitaxial layer is at least 10⁵ Ωcm.

6. The semiconductor device of claim 1, wherein an insolation voltage of the semi-insulating or insulating SiC epitaxial layer is at least 100V.

7. The semiconductor device of claim 1, wherein the GaN device is a high electron mobility transistor (HEMT).

8. The semiconductor device of claim 1, wherein a resistivity of the SiC substrate is equal to or less than about 0.010 Ωcm at room temperature

9. A method for manufacturing a semiconductor device comprising steps of:
providing an electronic conductive Silicon Carbide (SiC) substrate;
forming a semi-insulating or insulating SiC epitaxial layer formed on the electronic conductive SiC substrate; and
forming a Gallium Nitride (GaN) device on the semi-insulating or insulating SiC epitaxial layer.

10. The method for manufacturing a semiconductor device of claim 8, wherein a thickness of the semi-insulating or insulating SiC epitaxial layer is at least 5 μm.

11. The method for manufacturing a semiconductor device of claim 8, wherein a thickness of the semi-insulating or insulating SiC epitaxial layer is at least 10 μm.

12. The method for manufacturing a semiconductor device of claim 8, wherein the semi-insulating or insulating SiC epitaxial layer is grown directly on the conductive SiC substrate through chemical vapor deposition (CVD).

13. The method for manufacturing a semiconductor device of claim 8, wherein a resistivity of the semi-insulating or insulating SiC epitaxial layer is at least 10⁵ Ωcm.

14. The method for manufacturing a semiconductor device of claim 8, wherein an insolation voltage of the semi-insulating or insulating SiC epitaxial layer is at least 100V.

15. The method for manufacturing a semiconductor device of claim 8, wherein the GaN device is a high electron mobility transistor (HEMT).
